(19) United States
(12) Patent Application Publication
(10) Pub. No.: US 2024/0195390 A1
(43) Pub. Date: Jun. 13, 2024

(54) ACOUSTIC WAVE FILTER

(71) Applicant: Murata Manufacturing Co., Ltd., Nagaokakyo-shi (JP)

(72) Inventor: Akira NOGUCHI, Nagaokakyo-shi (JP)

(21) Appl. No.: 18/530,294

(22) Filed: Dec. 6, 2023

(30) Foreign Application Priority Data
Dec. 13, 2022 (JP) 2022-198887

(51) Int. Cl. H03H 9/64; H03H 9/25

(52) U.S. Cl. CPC H03H 9/6483; H03H 9/25; H03H 9/6489

(57) ABSTRACT

An acoustic wave filter includes a piezoelectric substrate, a functional electrode, a first wiring portion, a mounting substrate, and a second wiring portion. The functional electrode and the first wiring portion are located at a first major surface of the piezoelectric substrate. The first wiring portion is connected to the functional electrode. The second wiring portion is located at a third major surface of the mounting substrate. The second wiring portion is connected to ground. The first major surface of the piezoelectric substrate, and the third major surface of the mounting substrate are opposite to each other. An inter-wiring distance is less than a wiring width of the first wiring portion. The inter-wiring distance is a distance between the first wiring portion, and a portion of the second wiring portion that overlaps the first wiring portion in plan view seen in the direction of thickness of the mounting substrate.

### CROSS REFERENCE TO RELATED APPLICATIONS

This application claims the benefit of priority to Japanese Patent Application No. 2022-198887 filed on Dec. 13, 2022. The entire contents of this application are hereby incorporated herein by reference.

### BACKGROUND OF THE INVENTION

### 1. Field of the Invention

The present disclosure relates to an acoustic wave filter. More specifically, the present disclosure relates to an acoustic wave filter including a wiring portion.

### 2. Description of the Related Art

Japanese Unexamined Patent Application Publication No. 2018-098687 describes an acoustic wave device (acoustic wave filter) including an acoustic wave resonator. In the acoustic wave device according to Japanese Unexamined Patent Application Publication No. 2018-098687, the acoustic wave resonator is provided at a substrate (piezoelectric substrate), and the substrate is opposite to a package substrate (mounting substrate). A surface of the package substrate opposite to the substrate is provided with a wiring layer.

With acoustic wave filters, a situation may occur in which a wiring portion on a piezoelectric substrate becomes electromagnetically coupled to another wiring portion on the piezoelectric substrate. Electromagnetic coupling between wiring portions on the piezoelectric substrate results in propagation of a signal between two non-physically connected wiring portions. This may result in a situation where a signal that does not readily pass through an acoustic wave filter is output from the acoustic wave filter, leading to potential deterioration of the attenuation characteristics of the acoustic wave filter.

### SUMMARY OF THE INVENTION

Example embodiments of the present invention provide acoustic wave filters each with improved attenuation characteristics.

An acoustic wave filter according to an aspect of an example embodiment of the present disclosure includes a piezoelectric substrate, a functional electrode, a first wiring portion, a mounting substrate, and a second wiring portion. The piezoelectric substrate includes a first major surface and a second major surface that are opposite to each other. The functional electrode and the first wiring portion are located at the first major surface of the piezoelectric substrate. The first wiring portion is connected to the functional electrode. The mounting substrate includes a third major surface and a fourth major surface that are opposite to each other. The second wiring portion is located at the third major surface of the mounting substrate. The second wiring portion is connected to ground. The first major surface of the piezoelectric substrate, and the third major surface of the mounting substrate are opposite to each other. An inter-wiring distance is less than a wiring width of the first wiring portion. The inter-wiring distance is a distance between the first wiring portion, and a portion of the second wiring portion that overlaps the first wiring portion in plan view seen in a direction of thickness of the mounting substrate.

Acoustic wave filters according to example embodiments of the present disclosure allows for improved attenuation characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view of an acoustic wave device including an acoustic wave filter according to an example embodiment of the present invention.

FIG. 2 is a circuit diagram of an acoustic wave device according to an example embodiment of the present invention.

FIG. 3 is a bottom view of a acoustic wave device according to an example embodiment of the present invention with a mounting substrate not illustrated.

FIG. 4 is an enlarged view of a major portion of an acoustic wave device according to an example embodiment of the present invention.

FIG. 5 is a graph illustrating the relationship between the frequency of a signal input to each of an acoustic wave device according to an example embodiment of the present invention and an acoustic wave device according to a Comparative Example, and attenuation of the signal.

FIG. 6 is a graph illustrating, for an acoustic wave device according to an example embodiment of the present invention and the acoustic wave device according to the Comparative Example, the relationship between two values, the two values including the ratio between the wiring width of a wiring conductor portion and the inter-wiring distance, and the worst value of attenuation factor in an attenuation band.

### DETAILED DESCRIPTION OF THE EXAMPLE EMBODIMENTS

Acoustic wave devices including acoustic wave filters according to example embodiments are described below with reference to the drawings. The figures to which reference is to be made in the following description of the example embodiments are all schematic in nature, and the ratios between the sizes or thicknesses of individual components as depicted in the figures do not necessarily reflect the actual dimensional ratios.

### Example Embodiments

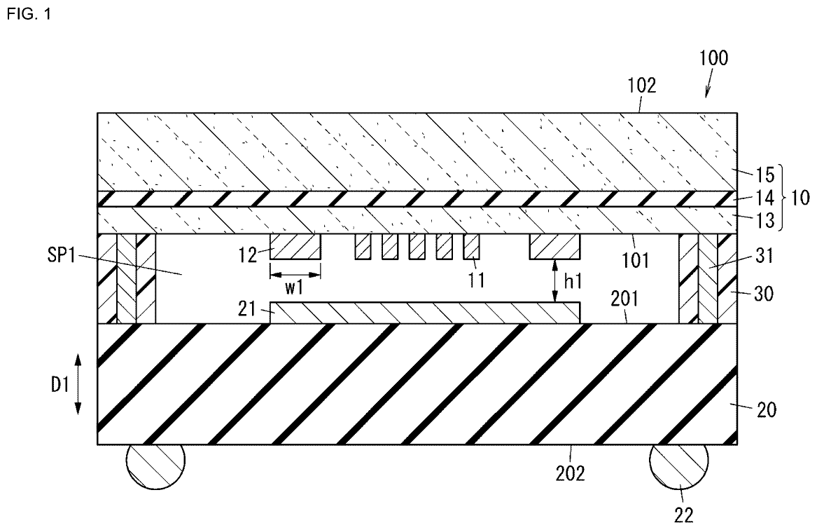

As illustrated in FIG. 1, an acoustic wave device 100 according to Example Embodiment 1 includes a piezoelectric substrate 10, a plurality of functional electrodes 11 (hereinafter sometimes referred to in the singular as “functional element 11” for convenience, as with other components or features disclosed herein), and a plurality of first wiring portions 12. The piezoelectric substrate 10 includes a first major surface 101 and a second major surface 102 that are opposite to each other. The functional electrode 11 and the first wiring portion 12 are located at the first major surface 101 of the piezoelectric substrate 10. The first wiring portions 12 are conductor portions though which a signal input to an acoustic wave filter 1 propagates.

The acoustic wave device 100 further includes a mounting substrate 20, a second wiring portion 21, and a plurality of external connection electrodes 22. The mounting substrate 20 includes a third major surface 201 and a fourth major surface 202 that are opposite to each other. The first major surface 101 of the piezoelectric substrate 10, and the third major surface 201 of the mounting substrate 20 are opposite to each other in a direction D1 of thickness of the mounting substrate 20. The second wiring portion 21 is located at the third major surface 201 of the mounting substrate 20. The second wiring portion 21 is connected to a ground electrode to which a ground potential is to be applied. The external connection electrode 22 is located at the fourth major surface 202 of the mounting substrate 20. The external connection electrode 22 includes a common electrode 23, an input electrode 24, an output electrode 25, and the ground electrode.

The acoustic wave device 100 further includes a spacer 30, and a via-conductor 31. The spacer 30 is interposed between the piezoelectric substrate 10 and the mounting substrate 20. The via-conductor 31 extends through the spacer 30 in the direction D1. The via-conductor 31 electrically connects the first wiring portion 12 and the external connection electrode 22 to each other.

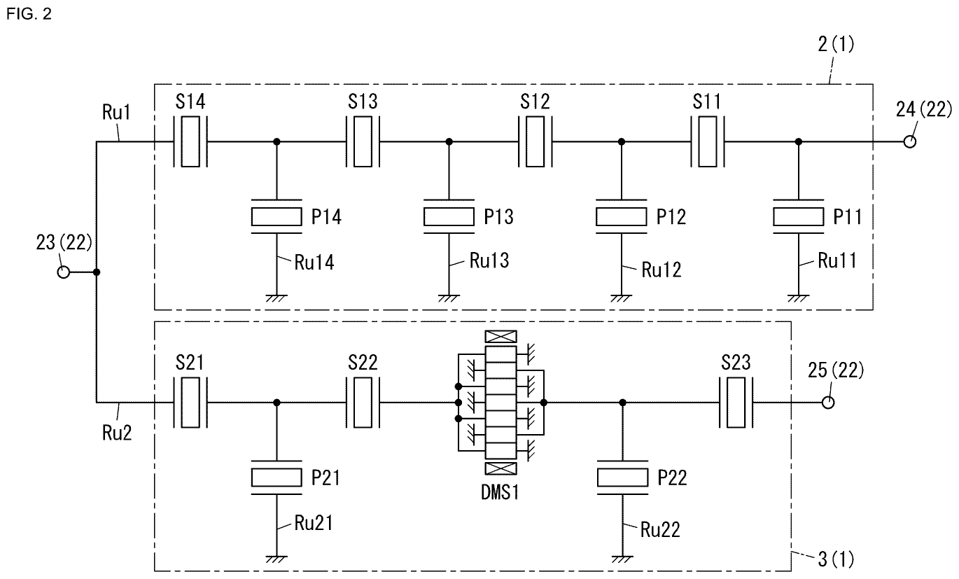

As illustrated in FIG. 2, the acoustic wave device 100 includes a transmit filter 2 and a receive filter 3 each defining and functioning as the acoustic wave filter 1. The transmit filter 2 includes a portion of the piezoelectric substrate 10, a plurality of functional electrodes 11, and a plurality of first wiring portions 12. The transmit filter 2 includes the input electrode 24 defining and functioning as an input terminal, and the common electrode 23 defining and functioning as an output terminal. The receive filter 3 includes a portion of the piezoelectric substrate 10, a plurality of functional electrodes 11, and a plurality of first wiring portions 12. The receive filter 3 includes the common electrode 23 defining and functioning as an input terminal, and the output electrode 25 defining and functioning as an output terminal.

The circuit configuration of the acoustic wave device 100 is first described below with reference to FIG. 2, and thereafter the structure of the acoustic wave device 100 is described in more detail.

The acoustic wave device 100 is, for example, a duplexer for use in a radio-frequency front-end circuit (not illustrated) of a communication apparatus (not illustrated). The communication apparatus includes an antenna. The acoustic wave device 100 includes, for example, the transmit filter 2 and the receive filter 3. Each of the transmit filter 2 and the receive filter 3 is the acoustic wave filter 1.

The common electrode 23 is a signal electrode common to the transmit filter 2 and the receive filter 3. The common electrode 23 is connected to, for example, an antenna. The transmit filter 2 is, for example, a filter whose pass band is the transmit frequency range of a first communication band. The first communication band is, for example, a communication band defined by the Third Generation Partnership Project (3GPP) (registered trademark) Long Term Evolution (LTE) (registered trademark) standard. The first communication band is, for example, a communication band (e.g., Band 20 or Band 28) used for communication in the frequency division duplex (FDD) communication mode. The first communication band is, however, not limited to the above-mentioned communication band. Alternatively, the first communication band may be a communication band used for communication in the time division duplex (TDD) mode.

The receive filter 3 is, for example, a filter whose pass band is the receive frequency range of a second communication band. The second communication band is, for example, a communication band defined by the 3GPP LTE standard or a communication band defined by the 5G NR standard. Although the second communication band is a communication band (e.g., Band 20) used for communication in the FDD communication mode, this is not intended to be limiting. Alternatively, the second communication band may be a communication band used for communication in the TDD mode.

The transmit filter 2 as the acoustic wave filter 1 is, for example, a ladder filter including a plurality of (e.g., eight) acoustic wave resonators as illustrated in FIG. 2. The acoustic wave resonators include, for example, four series-arm resonators S11, S12, S13, and S14, and four parallel-arm resonators P11, P12, P13, and P14. The four series-arm resonators S11, S12, S13, and S14 are located on a series-arm path Ru1, which is located between the common electrode 23 and the input electrode 24. That is, for the transmit filter 2, the input electrode 24 corresponds to a first terminal to which a signal is input. For the transmit filter 2, the common electrode 23 corresponds to a second terminal from which a signal is output.

The four series-arm resonators S11, S12, S13, and S14 are connected in series on the series-arm path Ru1. On the series-arm path Ru1 of the acoustic wave filter 1, the series-arm resonator S11, the series-arm resonator S12, the series-arm resonator S13, and the series-arm resonator S14 are arranged in the stated order as viewed from the input electrode 24.

The parallel-arm resonator P11 is located on a parallel-arm path Ru11. The parallel-arm path Ru11 is located between ground, and a portion of the series-arm path Ru1 that is located between the input electrode 24 and the series-arm resonator S11. The parallel-arm resonator P12 is located on a parallel-arm path Ru12. The parallel-arm path Ru12 is located between ground, and a portion of the series-arm path Ru1 that is located between the series-arm resonator S11 and the series-arm resonator S12. The parallel-arm resonator P13 is located on a parallel-arm path Ru13. The parallel-arm path Ru13 is located between ground, and a portion of the series-arm path Ru1 that is located between the series-arm resonator S12 and the series-arm resonator S13. The parallel-arm resonator P14 is located on a parallel-arm path Ru14. The parallel-arm path Ru14 is located between ground, and a portion of the series-arm path Ru1 that is located between the series-arm resonator S13 and the series-arm resonator S14.

The receive filter 3 is, for example, a ladder filter including a plurality of (e.g., six) acoustic wave resonators as illustrated in FIG. 2. The acoustic wave resonators include, for example, three series-arm resonators S21, S22, and S23, a longitudinally-coupled resonator DMS1, and two parallel-arm resonators P21 and P22. The three series-arm resonators S21, S22, and S23, and the longitudinally-coupled resonator DMS1 are located on a series-arm path Ru2, which is located between the common electrode 23 and the output electrode 25. That is, for the receive filter 3, the common electrode 23 corresponds to a first terminal to which a signal is input. For the receive filter 3, the output electrode 25 corresponds to a second terminal from which a signal is output.

The three series-arm resonators S21, S22, and S23, and the longitudinally-coupled resonator DMS1 are connected in series on the series-arm path Ru2. On the series-arm path Ru2 of the acoustic wave filter 1, the series-arm resonator S21, the series-arm resonator S22, the longitudinally-coupled resonator DMS1, and the series-arm resonator S23 are arranged in the stated order as viewed from the common electrode 23.

The parallel-arm resonator P21 is located on a parallel-arm path Ru21. The parallel-arm path Ru21 is located between ground, and a portion of the series-arm path Ru2 that is located between the series-arm resonator S21 and the series-arm resonator S22. The parallel-arm resonator P22 is located on a parallel-arm path Ru22. The parallel-arm path Ru22 is located between ground, and a portion of the series-arm path Ru2 that is located between the longitudinally-coupled resonator DMS1 and the series-arm resonator S23.

The structure of the acoustic wave device 100 is now described below.

As illustrated in FIG. 1, the acoustic wave device 100 includes the piezoelectric substrate 10, the functional electrodes 11, and the first wiring portions 12. As illustrated in FIG. 1, the acoustic wave device 100 includes the mounting substrate 20, and the second wiring portion 21. The acoustic wave device 100 further includes the spacer 30, the via-conductor 31, and the external connection electrodes 22. The spacer 30 is interposed between the piezoelectric substrate 10 and the mounting substrate 20. The spacer 30 is made of an insulating material. Examples of the insulating material include a resin material such as polyimide. The via-conductor 31 extends through the spacer 30. The via-conductor 31 electrically connects the first wiring portion 12 and the external connection electrode 22 to each other. The spacer 30 is frame-shaped. The acoustic wave device 100 includes a hollow space SP1. The hollow space SP1 is bounded by the piezoelectric substrate 10, the mounting substrate 20, and the spacer 30. Each external connection electrode 22 is, for example, a conductive bump.

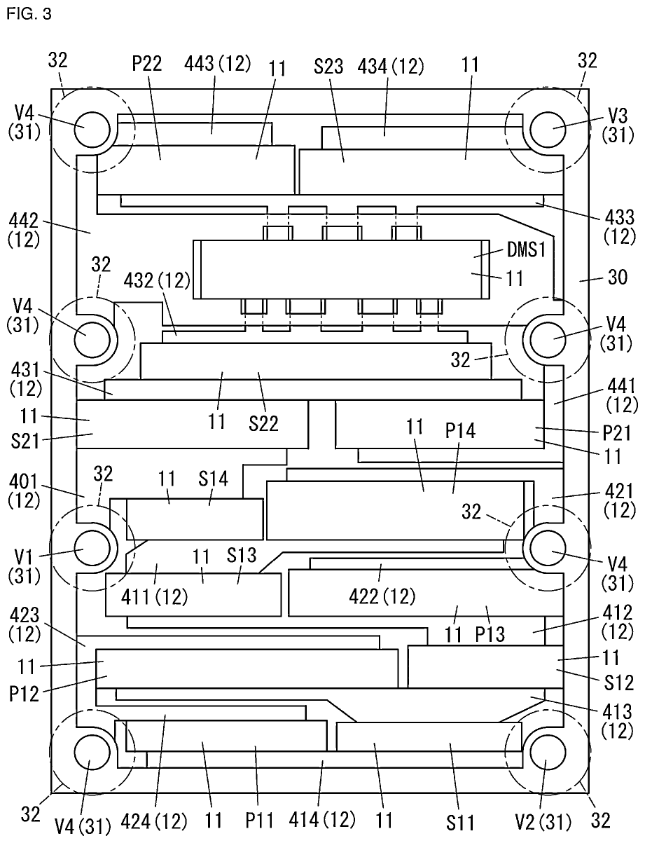

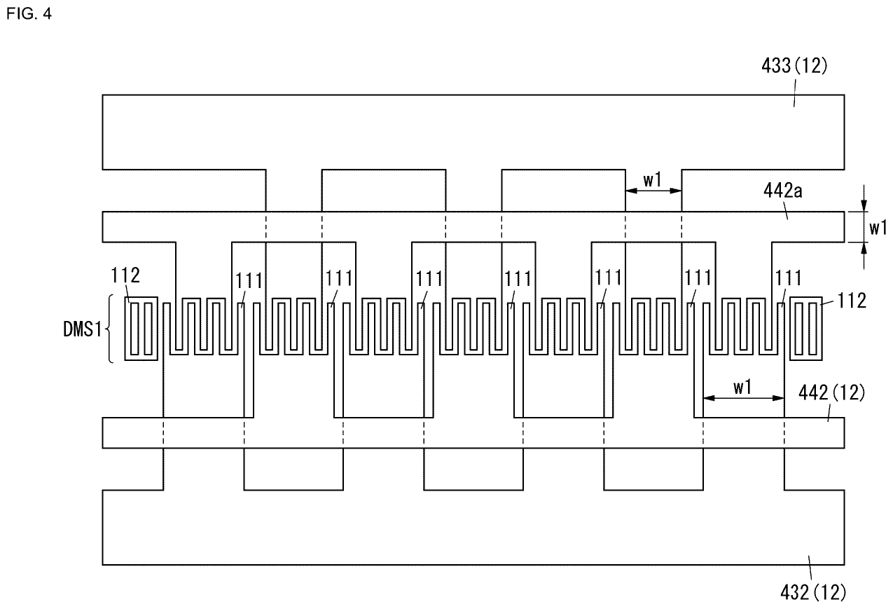

The acoustic wave filter 1 is an acoustic wave filter using a surface acoustic wave. As illustrated in FIGS. 1 and 3, the acoustic wave filter 1 includes the piezoelectric substrate 10, and a plurality of functional electrodes 11 each defining a portion of the corresponding one of a plurality of acoustic wave resonators. Each functional electrode 11 includes an interdigital transducer (IDT) electrode 111 (see FIG. 4), and a pair of reflectors 112 (see FIG. 4). Each acoustic wave resonator is thus a surface acoustic wave (SAW) resonator. At least one of the acoustic wave resonators may be a bulk acoustic wave (BAW) resonator with a piezoelectric layer sandwiched by upper and lower electrodes. In this case, the functional electrodes 11 may include the upper and lower electrodes of such a BAW resonator.

More specifically, as illustrated in FIG. 3, the transmit filter 2 includes four functional electrodes 11 corresponding to the series-arm resonators S11, S12, S13, and S14, which are acoustic wave resonators. The transmit filter 2 includes four functional electrodes 11 corresponding to the parallel-arm resonators P11, P12, P13, and P14, which are acoustic wave resonators. Each functional electrode 11 includes a single IDT electrode 111, and a pair of reflectors 112.

The receive filter 3 includes three functional electrodes 11 corresponding to the series-arm resonators S21, S22, and S23. Each functional electrode 11 includes a single IDT electrode 111, and a pair of reflectors 112. The receive filter 3 includes two functional electrodes 11 corresponding to the parallel-arm resonators P21 and P22. Each functional electrode 11 includes a single IDT electrode 111, and a pair of reflectors 112. Further, the receive filter 3 includes the functional electrode 11 corresponding to the longitudinally-coupled resonator DMS1. The functional electrode 11 corresponding to the longitudinally-coupled resonator DMS1 includes seven IDT electrodes 111, and a pair of reflectors 112 as illustrated in FIG. 4.

As illustrated in FIG. 1, the piezoelectric substrate 10 includes the first major surface 101 and the second major surface 102 that are opposite to each other in the direction D1 of thickness of the piezoelectric substrate 10. In plan view seen in the direction of thickness of the piezoelectric substrate 10, the piezoelectric substrate 10 has a rectangular outer edge. The piezoelectric substrate 10 has a thickness of, for example, greater than or equal to about 50 μm and less than or equal to about 200 μm.

The piezoelectric substrate 10 includes, for example, a high-acoustic-velocity support substrate 15, a low-acoustic-velocity film 14, and a piezoelectric layer 13. The low-acoustic-velocity film 14 is located on the high-acoustic-velocity support substrate 15. The piezoelectric layer 13 is located on the low-acoustic-velocity film 14. The piezoelectric layer 13 has piezoelectricity. In the high-acoustic-velocity support substrate 15, a bulk wave propagates at an acoustic velocity higher than the acoustic velocity of an acoustic wave that propagates in the piezoelectric layer 13. In this case, the bulk wave that propagates in the high-acoustic-velocity support substrate 15 refers to the bulk wave with the lowest acoustic velocity among a plurality of bulk waves that propagate in the high-acoustic-velocity support substrate 15. The low-acoustic-velocity film 14 is a film in which a bulk wave propagates at an acoustic velocity lower than the acoustic velocity of the bulk wave that propagates in the piezoelectric layer 13.

The material of the piezoelectric layer 13 is, for example, selected from the group consisting of lithium tantalate and lithium niobate. According to the present example embodiment, the material of the piezoelectric layer 13 is lithium tantalate. The piezoelectric layer 13 preferably has a thickness of, for example, less than or equal to about 3.5λ, where λ is the wavelength of an acoustic wave as determined by the pitch of the electrode fingers of an IDT electrode included in the functional electrode 11. According to the present example embodiment, the piezoelectric layer 13 has a thickness of, for example, about 1 μm.

The material of the high-acoustic-velocity support substrate 15 includes, for example, silicon. In this case, the high-acoustic-velocity support substrate 15 is a silicon substrate. The silicon substrate preferably has a thickness of, for example, greater than or equal to about 10λ and less than or equal to about 180 μm. The silicon substrate has a resistivity of, for example, greater than or equal to about 1 kΩcm, preferably greater than or equal to about 2 kΩcm, and more preferably greater than or equal to about 4 kΩcm. The silicon substrate includes, for example, a bulk region near the low-acoustic-velocity film 14, and a surface region opposite from the low-acoustic-velocity film 14. The surface region includes the second major surface 102 of the piezoelectric substrate 10. The surface region has a thickness of, for example, greater than or equal to about 1 nm and less than or equal to about 700 nm. According to the present example embodiment, the surface region has a thickness of, for example, about 300 nm. The bulk region is a single-crystal silicon layer. The single-crystal silicon layer is the remaining portion of the single-crystal silicon substrate excluding the surface region formed in or on the single-crystal silicon substrate. The surface region is, for example, an amorphous silicon layer. The amorphous silicon layer is formed by, for example, deteriorating the lattice structure of part of the single-crystal silicon substrate from which the high-acoustic-velocity support substrate 15 is made. The surface region is formed through, for example, implantation of ions of at least one element selected from the group consisting of argon, silicon, oxygen, and carbon. Alternatively, the surface region may be formed through, for example, exposure of the single-crystal silicon substrate to radiation. It may suffice that the material of the high-acoustic-velocity support substrate 15 includes, for example, at least one selected from the group consisting of silicon, aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

The material of the low-acoustic-velocity film 14 includes, for example, silicon oxide and silicon nitride. The material of the low-acoustic-velocity film 14 is not limited to the combination of silicon oxide and silicon nitride. The material of the low-acoustic-velocity film 14 may be, for example, a compound including fluorine, carbon, or boron added to silicon oxide, glass, silicon oxynitride, tantalum oxide, or silicon oxide, or a material including any one of the above-mentioned materials as a major component. The low-acoustic-velocity film 14 preferably has a thickness of less than or equal to about 2λ, for example. According to the present example embodiment, the low-acoustic-velocity film 14 has a thickness of, for example, about 670 nm.

As illustrated in FIG. 3, the functional electrodes 11 are located at the first major surface 101 of the piezoelectric substrate 10. Each functional electrode 11 includes the IDT electrode 111 and the reflectors 112. As for the IDT electrodes 111 corresponding to the series-arm resonators S11 to S14 and S21 to S23 or the parallel-arm resonators P11 to P14, P21, and P22, two reflectors 112 are located adjacent to the IDT electrode 111. As for the seven IDT electrodes 111 corresponding to the longitudinally-coupled resonator DMS1, two reflectors 112 are arranged adjacent to the seven IDT electrodes 111 in a direction in which the IDT electrodes 111 are arranged. The two reflectors 112 each reflect an acoustic wave propagating in a direction as determined by the functional electrode 11 located between the two reflectors 112. The reflectors 112 are, for example, grating-type reflectors.

The functional electrodes 11 have electrical conductivity. Examples of the material of the functional electrodes 11 include aluminum, copper, platinum, gold, silver, titanium, nickel, chromium, molybdenum, and tungsten, or an alloy including any one of these metals as its major component. The functional electrodes 11 may be of a structure including a stack of metal films made of these metals or alloys. The functional electrodes 11 each include, for example, a stack of a first metal film and a second metal film. The first metal film includes a titanium film located on the first major surface 101 of the piezoelectric substrate 10. The second metal film includes two layers including an aluminum film and a titanium film that are located on the first metal film. The first metal film defines and functions as an adhesion film. Although the first metal film is made of titanium, the material of the first metal film is not limited to titanium but may be, for example, chromium or nickel-chromium. Although the second metal film is made of aluminum and titanium, this is not intended to be limiting. For example, the material of the second metal film may include aluminum and copper. The first metal film has a thickness less than the thickness of the second metal film. The thickness of the first metal film is, for example, about 375 nm. The thickness of the second metal layer is, for example, about 4 nm.

As illustrated in FIG. 3, the first wiring portions 12 are located at the first major surface 101 of the piezoelectric substrate 10. Each first wiring portion 12 is connected to the functional electrode 11 and the via-conductor 31. The via-conductor 31 includes a first via-conductor V1, a second via-conductor V2, a third via-conductor V3, and a plurality of fourth via-conductors V4. The first via-conductor V1 is connected to the common electrode 23. The second via-conductor V2 is connected to the input electrode 24. The third via-conductor V3 is connected to the output electrode 25. Each fourth via-conductor V4 is connected to ground. Each via-conductor 31 has, for example, a cylindrical shape.

As illustrated in FIG. 3, the first wiring portions 12 include first wiring portions 401 to 443. In the following description, when reference is made to any one of the first wiring portions 401 to 443 with no distinction therebetween, the corresponding first wiring portion will be referred to as “first wiring portion 12.” Although the first wiring portion 442 is depicted in FIG. 3 as intersecting the first wiring portions 432 and 433, the first wiring portion 442 is not electrically connected to the first wiring portions 432 and 433 at its intersection with each of these wiring portions. More specifically, the first wiring portion 442 is located on an insulating layer located over the first wiring portions 432 and 433.

The first wiring portion 401 is connected to the first via-conductor V1, and the series-arm resonators S14 and S21. The first wiring portion 401 includes a portion of the series-arm path Ru1, and a portion of the series-arm path Ru2. The first wiring portion 411 is connected to the series-arm resonators S14 and S13, and the parallel-arm resonator P14. The first wiring portion 411 includes a portion of the series-arm path Ru1, and a portion of the parallel-arm path Ru14. The first wiring portion 421 is connected to the parallel-arm resonator P14, and the fourth via-conductor V4. The first wiring portion 421 includes a portion of the parallel-arm path Ru14. The first wiring portion 412 is connected to the series-arm resonators S13 and S12, and the parallel-arm resonator P13. The first wiring portion 412 includes a portion of the series-arm path Ru1, and a portion of the parallel-arm path Ru13. The first wiring portion 422 is connected to the parallel-arm resonator P13, and the fourth via-conductor V4. The first wiring portion 422 includes a portion of the parallel-arm path Ru13. The first wiring portion 413 is connected to the series-arm resonators S12 and S11, and the parallel-arm resonator P12. The first wiring portion 413 includes a portion of the series-arm path Ru1, and a portion of the parallel-arm path Ru12. The first wiring portion 423 is connected to the parallel-arm resonator P12, and the fourth via-conductor V4. The first wiring portion 423 includes a portion of the parallel-arm path Ru12. The first wiring portion 414 is connected to the series-arm resonator S11, the parallel-arm resonator P11, and the second via-conductor V2. The first wiring portion 414 includes a portion of the series-arm path Ru1, and a portion of the parallel-arm path Ru11. The first wiring portion 424 is connected to the parallel-arm resonator P11, and the fourth via-conductor V4. The first wiring portion 424 includes a portion of the parallel-arm path Ru11.

The first wiring portion 431 is connected to the series-arm resonators S21 and S22, and the parallel-arm resonator P21. The first wiring portion 431 includes a portion of the series-arm path Ru2, and a portion of the parallel-arm path Ru21. The first wiring portion 441 is connected to the parallel-arm resonator P21, and the fourth via-conductor V4. The first wiring portion 441 includes a portion of the parallel-arm path Ru21. The first wiring portion 432 is connected to the series-arm resonator S22, and the longitudinally-coupled resonator DMS1. The first wiring portion 432 includes a portion of the series-arm path Ru2. The first wiring portion 442 is connected to the longitudinally-coupled resonator DMS1, and the fourth via-conductor V4. The first wiring portion 433 is connected to the longitudinally-coupled resonator DMS1, the series-arm resonator S23, and the parallel-arm resonator P22. The first wiring portion 433 includes a portion of the series-arm path Ru2, and a portion of the parallel-arm path Ru22. The first wiring portion 443 is connected to the parallel-arm resonator P22, and the fourth via-conductor V4. The first wiring portion 443 includes a portion of the parallel-arm path Ru22. The first wiring portion 434 is connected to the series-arm resonator S23, and the third via-conductor V3. The first wiring portion 434 includes a portion of the series-arm path Ru2.

As illustrated in FIG. 1, the mounting substrate 20 includes the third major surface 201 and the fourth major surface 202. The third major surface 201 and the fourth major surface 202 are opposite to each other in the direction of thickness of the mounting substrate 20. The third major surface 201 of the mounting substrate 20 is opposite to the first major surface 101 of the piezoelectric substrate 10.

The mounting substrate 20 is a multilayer substrate including a plurality of stacked dielectric layers. The mounting substrate 20 includes a plurality of conductive layers, and a plurality of via-conductors. The via-conductors are used to electrically connect the second wiring portion 21 and the ground electrode to each other. The via-conductors are also used to electrically connect the first wiring portion 12 and the external connection electrode 22 to each other via the via-conductor 31.

The second wiring portion 21 is located at the third major surface 201 of the mounting substrate 20. The second wiring portion 21 is connected to the ground electrode. In plan view as seen in the direction D1 of thickness of the mounting substrate 20, the second wiring portion 21 overlaps the first wiring portion 12. More specifically, in plan view seen in the direction D1 of thickness of the mounting substrate 20, at least one first wiring portion 12 overlaps at least partly a portion of the second wiring portion 21. The second wiring portion 21 corresponds to a second wiring portion.

The distance between the first wiring portion 12 and the second wiring portion 21 is defined as an inter-wiring distance h1. The inter-wiring distance h1 is, for example, about 18 μm. As described above, in plan view seen in the direction D1 of thickness of the mounting substrate 20, at least one first wiring portion 12 overlaps at least partly a portion of the second wiring portion 21. Therefore, the inter-wiring distance h1 between the first wiring portion 12 and the second wiring portion 21 is the distance between the first wiring portion 12, and a portion of the second wiring portion 21 that overlaps the first wiring portion 12 in plan view seen in the direction D1 of thickness of the mounting substrate 20.

The first wiring portion 12 has a wiring width w1 described below. The wiring width w1 of the first wiring portion 12 is the width of the first wiring portion 12 in a direction transverse to the direction of signal flow in the first wiring portion 12. With regard to, for example, the series-arm paths Ru1 and Ru2 located between the input terminal and the output terminal, the term “direction of signal flow” as used herein refers to a direction that points from the input terminal to the output terminal. With regard to, for example, the parallel-arm paths Ru11 to Ru22, the term “direction of signal flow” refers to a direction that points from the series-arm path Ru1 or the series-arm path Ru2 to ground. More specifically, the wiring width w1 of the first wiring portion 12 is the smallest possible value of the width of the first wiring portion 12 in a direction transverse to the direction of signal flow in the first wiring portion 12.

A portion of the first wiring portion 12 that lies within a surrounding region 32 of the via-conductor 31 is not included in the calculation of the wiring width w1 of the first wiring portion 12. In this regard, a portion of the first wiring portion 12 that lies within the surrounding region 32 refers to a portion where the distance from the central axis of the via-conductor 31 is less than or equal to the width of the via-conductor 31. For example, if the via-conductor 31 is in the form of a cylinder with a radius r, the surrounding region 32 refers to a region where the distance from the central axis of the via-conductor 31 is less than or equal to 2r. In the vicinity of the contact point between the via-conductor 31 and the first wiring portion 12, the via-conductor 31 and the first wiring portion 12 may, in some cases, integrally define a wiring line. Accordingly, with the via-conductor 31 and the first wiring portion 12 regarded as a single conductor, the wiring width of the first wiring portion 12 within the surrounding region 32 may, in some cases, be less than the wiring width of the single conductor. Therefore, for example, the wiring width w1 of the first wiring portion 424 is the smallest value that, in a portion of the first wiring portion 424 not lying within the surrounding region 32, the width of the first wiring portion 424 can take in a direction transverse to the direction of signal flow. In the acoustic wave filter 1 according to the present example embodiment, the first wiring portion 12 with the smallest wiring width w1 corresponds to each of the first wiring portions 432 and 433 connected to the longitudinally-coupled resonator DMS1. Alternatively, however, the first wiring portion 12 with the smallest wiring width w1 may be another first wiring portion 12 of the first wiring portions 12.

FIG. 4 is a schematic enlarged plan view of the functional electrode 11 of the longitudinally-coupled resonator DMS1, and the first wiring portions 432, 442, and 433 connected to the longitudinally-coupled resonator DMS1. As illustrated in FIG. 4, the functional electrode 11 of the longitudinally-coupled resonator DMS1 includes a plurality of IDT electrodes 111, and a plurality of reflectors 112. The first wiring portion 432 provides electrical connection between the functional electrode 11 corresponding to the series-arm resonator S22, and some of the IDT electrodes 111 of the longitudinally-coupled resonator DMS1. The first wiring portion 433 provides electrical connection between some of the IDT electrodes 111 of the longitudinally-coupled resonator DMS1, and each of the functional electrode 11 corresponding to the series-arm resonator S23 and the functional electrode 11 corresponding to the parallel-arm resonator P22. The first wiring portion 442 provides electrical connection between some of the IDT electrodes 111 of the longitudinally-coupled resonator DMS1, and the fourth via-conductor V4. As in FIG. 3, at locations where the first wiring portion 442 overlaps the first wiring portions 432 and 433 in FIG. 4, the first wiring portion 442 is spaced apart from and not electrically connected to the first wiring portion 432 or 433 in the direction D1 of thickness of the mounting substrate 20.

In the first wiring portion 432, the direction of signal flow is upward from a lower portion of FIG. 4. Accordingly, the wiring width w1 of the first wiring portion 432 coincides with the value of the smallest one of the respective widths of the first, third, fifth, and seventh IDT electrodes 111 of the seven IDT electrodes 111 as seen from the end of the arrangement of the IDT electrodes 111. The respective widths of the first, third, fifth, and seventh IDT electrodes 111 as seen from the end of the arrangement of the IDT electrodes 111 are, for example, about 69 μm, about 78 μm, about 98 μm, and about 51 μm. Accordingly, the wiring width w1 of the first wiring portion 432 is, for example, about 51 μm.

In the first wiring portion 433, the direction of signal flow is upward from a lower portion of FIG. 4. Accordingly, the wiring width w1 of the first wiring portion 433 coincides with the value of the smallest one of the respective widths of the second, fourth, and sixth IDT electrodes 111 of the seven IDT electrodes 111 as seen from the end of the arrangement of the IDT electrodes 111. The respective widths of the second, fourth, and sixth IDT electrodes 111 from the end of the arrangement of the IDT electrodes 111 are, for example, about 58 μm, about 83 μm, and about 38 μm. Accordingly, the wiring width w1 of the first wiring portion 433 is, for example, about 38 μm.

In the first wiring portion 442, the direction of signal flow is first upward/downward from the functional electrode 11 of the longitudinally-coupled resonator DMS1 toward a portion 442a of the first wiring portion 442 in FIG. 4, and then from right to left through the portion 442a. Therefore, the wiring width w1 of the first wiring portion 442 coincides with the width in the up/down direction of the portion 442a. The wiring width w1 of the first wiring portion 442 is, for example, about 20 μm.

The first wiring portion 414 includes the following portions: a portion in contact with the parallel-arm resonator P11, a portion in contact with the series-arm resonator S11, a portion connecting the parallel-arm resonator P11 and the series-arm resonator S11, and a portion connecting the series-arm resonator S11 and the second via-conductor V2. The width of the portion in contact with the parallel-arm resonator P11, and the wiring width of the portion of the first wiring portion 414 in contact with the series-arm resonator S11 respectively coincide with the width of the IDT electrode of the parallel-arm resonator P11, and the width of the IDT electrode of the series-arm resonator S11, and are, for example, about 377 μm and about 349 μm, respectively. In this regard, if either the portion connecting the parallel-arm resonator P11 and the series-arm resonator S11, or the portion connecting the series-arm resonator S11 and the second via-conductor V2 has a width less than the width of the IDT electrode of the series-arm resonator S11, the wiring width w1 of the first wiring portion 414 in this case is less than about 349 μm. The wiring width w1 of the first wiring portion 414 is, for example, about 18 μm.

In the acoustic wave device 100 according to the present example embodiment, the inter-wiring distance h1 between the first wiring portion 12 and the second wiring portion 21 is less than the wiring width w1 of the first wiring portion 12. more specifically, the inter-wiring distance h1 between the first wiring portion 12 and the second wiring portion 21 is less than the wiring width w1 of at least one first wiring portion 12. As will be described later, this configuration makes it possible to reduce deterioration of the attenuation characteristics of the acoustic wave filter 1 resulting from electromagnetic coupling between the first wiring portion 12 and another first wiring portion 12. In this regard, the wiring width w1 of the first wiring portion 12 refers to the wiring width w1 of the first wiring portion 12 at a location where the wiring width in a direction transverse to the direction of signal flow in the first wiring portion 12 is at its smallest. For example, in a case where the first wiring portion 12 has a non-constant wiring width, if the inter-wiring distance h1 is less than the wiring width of a thick portion of the first wiring portion 12 and greater than or equal to the wiring width of a thin portion of the first wiring portion 12, this may potentially result in insufficient reduction of electromagnetic coupling between the first wiring portion 12 and another first wiring portion 12. By contrast, if the inter-wiring distance h1 is less than the wiring width w1 of the thin portion of the first wiring portion 12, this allows for sufficient reduction of electromagnetic coupling between the first wiring portion 12 and another first wiring portion 12.

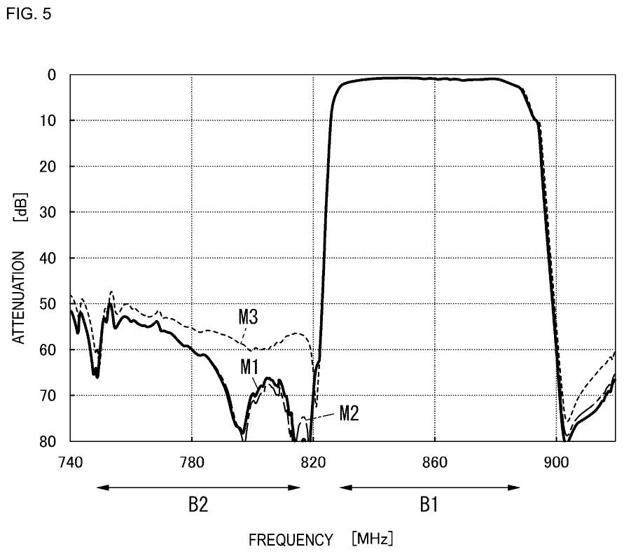

FIG. 5 is a graph illustrating, for each of the acoustic wave device 100 according to the present example embodiment and an acoustic wave device according to Comparative Example, the relationship between the frequency of an input signal, and attenuation of the signal. More specifically, FIG. 5 illustrates, for each of samples M1 to M3, the relationship between the frequency of a signal input to the sample, and attenuation of the signal. The samples M1 and M2 each correspond to the acoustic wave device 100 according to the present example embodiment. Specifically, the sample M1 represents the receive filter 3 within the acoustic wave device 100 in which the wiring width w1 of the first wiring portion 12 is about 18 μm and in which the inter-wiring distance h1 between the first wiring portion 12 and the second wiring portion 21 is about 8 μm, for example. The receive filter 3 corresponding to the sample M1 has a pass band B1 that includes, for example, the receive frequency range of Band 20. The receive filter 3 corresponding to the sample M1 has an attenuation band B2 that includes, for example, the transmit frequency range of Band 20 and the transmit frequency range of Band 28. The attenuation band B2 is lower in frequency than the pass band B1. The sample M2 represents the receive filter 3 within the acoustic wave device 100 that corresponds to the sample M1 and in which the inter-wiring distance h1 between the first wiring portion 12 and the second wiring portion 21 is about 18 μm, for example. By contrast, the sample M3 corresponds to an acoustic wave device according to Comparative Example. Specifically, the sample M3 represents a receive filter within an acoustic wave device that corresponds to the sample M1 and in which the inter-wiring distance h1 between the first wiring portion 12 and the second wiring portion 21 is about 78 μm, for example. That is, the samples M1, M2, and M3 differ from each other only in the inter-wiring distance h1 between the first wiring portion 12 and the second wiring portion 21.

As illustrated in FIG. 5, with regard to the attenuation in the pass band B1, the differences between the samples M1 to M3 are very small. By contrast, with regard to the attenuation in the attenuation band B2, the sample M3 has an attenuation factor less than the attenuation factor of the sample M1 and the attenuation factor of the sample M2. In other words, with respect to the attenuation band B2, the sample M3 has attenuation characteristics inferior to the attenuation characteristics of the sample M1 and the attenuation characteristics of the sample M2.

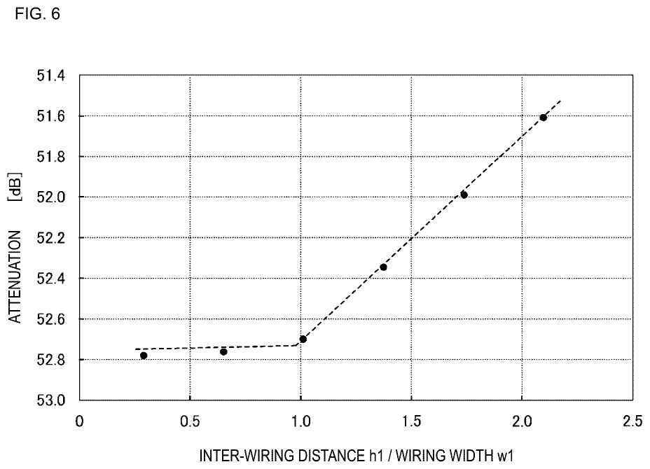

FIG. 6 is a graph illustrating, for the acoustic wave device 100 according to the present example embodiment and the acoustic wave device according to Comparative Example, the relationship between the following two values: the ratio h1/w1 between the wiring width w1 of the first wiring portion 12 and the inter-wiring distance h1, and the worst value of attenuation factor in the attenuation band B2. The ratio h1/w1 between the wiring width w1 of the first wiring portion 12 and the inter-wiring distance h1 is a value obtained by dividing the inter-wiring distance h1 by the wiring width w1 of the first wiring portion 12. More specifically, the wiring width w1 of the first wiring portion 12 is about 18 μm, and thus the ratio h1/w1 of the inter-wiring distance h1 to the wiring width w1 is a value obtained by dividing the inter-wiring distance h1 by about 18 μm, which is the wiring width w1 of the first wiring portion 12, for example. The worst value of attenuation factor in the attenuation band B2 refers to the attenuation of a signal at the frequency at which the signal attenuation is at its minimum, among signals at various frequencies falling within the attenuation band B2 of the receive filter 3 of the acoustic wave device 100 or the receive filter of the acoustic wave device according to Comparative Example. That is, with regard to the worst value of attenuation factor in the attenuation band B2, the larger its absolute value (the lower the corresponding position in FIG. 6), the better the attenuation characteristics in the attenuation band B2, whereas the smaller its absolute value (the higher the corresponding position in FIG. 6), the worse the attenuation characteristics in the attenuation band B2.

As illustrated in FIG. 6, when the ratio h1/w1 between the wiring width w1 of the first wiring portion 12 and the inter-wiring distance h1 is greater than or equal to 1, the greater the ratio h1/w1 between the wiring width w1 of the first wiring portion 12 and the inter-wiring distance h1, the closer the worst value of attenuation factor in the attenuation band B2 is to 0 dB. That is, the greater the ratio h1/w1 between the wiring width w1 of the first wiring portion 12 and the inter-wiring distance h1, the greater the deterioration of the attenuation characteristics of the corresponding acoustic wave filter. By contrast, when the ratio h1/w1 between the wiring width w1 of the first wiring portion 12 and the inter-wiring distance h1 is less than or equal to 1, the worst value of attenuation factor in the attenuation band B2 does not change substantially. That is, due to the inter-wiring distance h1 being less than or equal to the wiring width w1 of the first wiring portion 12, deterioration of the attenuation characteristics of the acoustic wave filter 1 can be reduced.

A conceivable factor for this is electromagnetic coupling between the first wiring portion 12 and another first wiring portion 12. That is, the greater the inter-wiring distance h1 between the first wiring portion 12 and the second wiring portion 21, the weaker the electromagnetic coupling between the first wiring portion 12 and the second wiring portion 21 and, consequently, the more likely electromagnetic coupling is to be occur between the first wiring portion 12 and another first wiring portion 12. If electromagnetic coupling occurs between the first wiring portion 12 and another first wiring portion 12, a portion of a signal flowing through the series-arm path Ru1 or Ru2 may in some cases bypass part or all of the series-arm resonators S11 to S23 or the longitudinally-coupled resonator DMS1. Further, if electromagnetic coupling occurs between the first wiring portion 12 and another first wiring portion 12, a portion of a signal that is to pass from each of the parallel-arm paths Ru11 to Ru22 to ground may pass into the series-arm path Ru1 or Ru2. If the phenomena mentioned above occur, a signal that does not readily pass through the acoustic wave filter 1 is output from the series-arm path Ru1 or Ru2 to the output terminal. This leads to deterioration of attenuation characteristics in the attenuation band B2.

It is now considered which first wiring portions 12 have influence on the attenuation characteristics in the attenuation band B2 of the acoustic wave filter 1 due to their mutual electromagnetic coupling. A first group of such first wiring portions 12 are the first wiring portions 401, 414, and 434 connected to the input terminal or output terminal of the acoustic wave filter 1. An example of the first wiring portion 12 connected to the input terminal of the acoustic wave filter 1 is the first wiring portion 401 connected to the first via-conductor V1, or the first wiring portion 414 connected to the second via-conductor V2. In this case, for example, a signal included in the attenuation band B2 of the acoustic wave filter 1 may in some cases flow from the input terminal of the series-arm path Ru1 or Ru2 to the output terminal without passing through at least one of the series-arm resonators S11 to S23. This may result in deterioration of attenuation characteristics in the attenuation band B2 of the acoustic wave filter 1.

An example of the first wiring portion 12 connected to the output terminal of the acoustic wave filter 1 is the first wiring portion 401 connected to the first via-conductor V1, or the first wiring portion 434 connected to the third via-conductor V3. In this case, for example, electromagnetic coupling may sometimes occur between two first wiring portions 12 included in the series-arm path Ru1 or Ru2, that is, between the first wiring portion 12 connected to the output terminal of the acoustic wave filter 1, and the above-mentioned first wiring portion 12. At this time, a signal included in the attenuation band B2 of the acoustic wave filter 1 may in some cases flow from the input terminal of the acoustic wave filter 1 to the output terminal without passing through at least one of the series-arm resonators S11 to S23. Further, electromagnetic coupling may sometimes occur between the above-mentioned first wiring portion 12, and the first wiring portion 12 included in the parallel-arm paths Ru11 to Ru22. At this time, a signal included in the attenuation band B2 of the acoustic wave filter 1 may sometimes flow from a parallel-arm path to the first wiring portion 12 connected to the output terminal of the acoustic wave filter 1. This results in deterioration of attenuation characteristics in the attenuation band B2 of the acoustic wave filter 1.

It is therefore preferable that the inter-wiring distance h1 be less than or equal to the wiring width w1 of the first wiring portion 401, 414, or 434 connected to the input terminal or output terminal of the acoustic wave filter 1.

A second group of first wiring portions 12 that have influence on the attenuation characteristics in the attenuation band B2 of the acoustic wave filter 1 due to their mutual electromagnetic coupling are the first wiring portions 421 to 424, 431, and 432 included in the parallel-arm paths Ru11 to Ru22 of the acoustic wave filter 1. Signals that flow to the parallel-arm paths Ru11 to Ru22 of the acoustic wave filter 1 are mainly signals included in the attenuation band B2 of the acoustic wave filter 1. This means an increased likelihood that, due to coupling of the first wiring portions 421 to 424, 431, and 432 with other first wiring portions 12, signals included in the attenuation band B2 of the acoustic wave filter 1 are output from the output electrode of the acoustic wave filter 1 via the series-arm path Ru1 or Ru2. It is therefore preferable that the inter-wiring distance h1 be less than or equal to the wiring width w1 of the first wiring portion 12 included in a parallel-arm path of the acoustic wave filter 1. In this regard, if the acoustic wave filter 1 includes a plurality of parallel-arm paths Ru11 to Ru22, a signal directed from the input electrode of the acoustic wave filter 1 to the ground electrode is relatively more likely to flow to one of the parallel-arm resonators P11 to P22 that has the lowest impedance. It is therefore preferable that the inter-wiring distance h1 be less than or equal to the wiring width w1 of a first wiring portion (one of the first wiring portions 421 to 424, 431, and 434) connected to a parallel-arm resonator (one of the parallel-arm resonators P11 to P22) that, among the parallel-arm resonators on the parallel-arm paths Ru11 to Ru22 of the acoustic wave filter 1, has the lowest impedance in the attenuation band B2 of the acoustic wave filter 1. The parallel-arm resonator having the lowest impedance is, for example, a parallel-arm resonator (one of the parallel-arm resonators P11 to P22) of the acoustic wave filter 1 that has the largest-sized functional electrode 11. For example, in the transmit filter 2, the parallel-arm resonator having the lowest impedance is the parallel-arm resonator P11 or P14. According to the present example embodiment, the attenuation band B2 of the receive filter 3 is lower in frequency than the pass band B1 of the receive filter 3. In this case, signals included in the attenuation band B2 of the receive filter 3 are likely to readily flow (due to low impedance) to the parallel-arm paths Ru11 to Ru22. This leads to improved attenuation characteristics in the attenuation band B2 of the receive filter 3. The above-mentioned configuration therefore results in reduced likelihood that the first wiring portions 421 to 424, 431, and 432 included in the parallel-arm paths Ru11 to Ru22 of the acoustic wave filter 1 become electromagnetically coupled to other first wiring portions 12. This allows for easy improvement of attenuation characteristics in the attenuation band B2 of the receive filter 3. As a result, for example, the attenuation band B2 of the receive filter 3 can be easily used as the pass band of the transmit filter 2 or of another filter.

The acoustic wave filter 1 according to the present example embodiment includes the piezoelectric substrate 10, the functional electrode 11, the first wiring portion 12, the mounting substrate 20, and the second wiring portion 21. The piezoelectric substrate 10 has the first major surface 101 and the second major surface 102 that are opposite to each other. The first wiring portion 12 includes the first wiring portion 12. The functional electrode 11 and the first wiring portion 12 are located at the first major surface 101 of the piezoelectric substrate 10. The mounting substrate 20 includes the third major surface 201 and the fourth major surface 202 that are opposite to each other. The second wiring portion 21 is located at the third major surface 201 of the mounting substrate 20. The second wiring portion 21 is connected to the ground electrode. The first major surface 101 of the piezoelectric substrate 10, and the third major surface 201 of the mounting substrate 20 are opposite to each other. The inter-wiring distance h1 is less than the wiring width w1 of the first wiring portion 12. The inter-wiring distance h1 is the distance between the first wiring portion 12, and a portion of the second wiring portion 21 that overlaps the first wiring portion 12 in plan view seen in the direction D1 of thickness of the mounting substrate 20. The configuration mentioned above increases the likelihood of electromagnetic coupling between the first wiring portion 12 and the second wiring portion 21, and reduces the likelihood of electromagnetic coupling between the first wiring portion 12 and another wiring line within the acoustic wave filter 1. The configuration mentioned above therefore makes it possible to reduce the risk that, due to electromagnetic coupling between wiring lines within the acoustic wave filter 1, a signal that does not readily pass through the acoustic wave filter 1 is output from the acoustic wave filter 1. That is, the configuration mentioned above allows for improved attenuation characteristics of the acoustic wave filter 1.

In the acoustic wave filter 1 according to the present example embodiment, the wiring width w1 of the first wiring portion 12 is the wiring width w1 of the first wiring portion 12 at a location where the wiring width of the first wiring portion 12 is at its smallest in a direction transverse to the direction of signal flow in the first wiring portion 12. This makes it possible to, if the first wiring portion 12 has a non-constant wiring width, prevent a situation where reduction of potential electromagnetic coupling between the first wiring portion 12 and another first wiring portion 12 becomes insufficient due to the inter-wiring distance h1 being greater than or equal to the wiring width w1 of a portion of the first wiring portion 12.

The acoustic wave filter 1 according to the present example embodiment includes the common electrode 23 and the input electrode 24 that are electrodes to which a signal is input, and the output electrode 25 and the common electrode 23 that are electrodes from which a signal is output. The first wiring portions 401, 414, and 434 are connected to at least one of the common electrode 23, the input electrode 24, or the output electrode 25. This helps to reduce potential deterioration of the attenuation characteristics of the acoustic wave filter 1, which may occur when a signal input to the acoustic wave filter 1 bypasses a series-arm resonator before being output from the acoustic wave filter 1 or may occur when a signal that is input to the acoustic wave filter 1 and that is to pass to ground is output from the acoustic wave filter 1.

The acoustic wave filter 1 according to the present example embodiment includes the common electrode 23 and the input electrode 24 that each represent an electrode to which a signal is input, and the output electrode 25 and the common electrode 23 that each represent an electrode from which a signal is output. The acoustic wave filter 1 includes the parallel-arm resonators P11 to P22 located on the parallel-arm paths Ru11 to Ru22. The parallel-arm paths Ru11 to Ru22 are each located between ground, and the series-arm path Ru1 or the series-arm path Ru2. The series-arm path Ru2 connects the common electrode 23 and the output electrode 25. The series-arm path Ru1 connects the input electrode 24 and the common electrode 23. On the parallel-arm paths Ru11 to Ru22, the first wiring portions 421 to 424, 441, and 443 are connected in series with the parallel-arm resonators P11 to P22. The configuration mentioned above makes it possible to reduce the risk that signals that are to pass to ground from the series-arm paths Ru1 and Ru2 via the parallel-arm paths Ru11 to Ru22 pass into the series-arm paths Ru1 and Ru2 due to electromagnetic coupling between wiring lines. The configuration mentioned above therefore allows for improved attenuation characteristics of the acoustic wave filter 1.

According to the present example embodiment, the receive filter 3 has the attenuation band B2 that is lower in frequency than the pass band B1 of the receive filter 3. As a result, the parallel-arm paths Ru11 to Ru22 have an increased influence on the attenuation characteristics in the attenuation band B2 of the receive filter 3. The configuration mentioned above therefore allows the attenuation characteristics of the acoustic wave filter 1 to be improved by reducing potential electromagnetic coupling of the first wiring portions 421 to 424, 441, and 443 with other wiring lines.

According to the present example embodiment, the acoustic wave filter 1 includes the parallel-arm resonators P11 to P22. The first wiring portions 421 to 424, 441, and 443 are connected to one of the parallel-arm resonators P11 to P22 that has the lowest impedance in the attenuation band B2 of the receive filter 3. The configuration mentioned above makes it possible to reduce the risk that a signal passes from one of the first wiring portions 421 to 424, 441, and 443 through which the largest current flows, into the series-arm path Ru1 or Ru2 due to electromagnetic coupling between wiring lines. The configuration mentioned above therefore allows for improved attenuation characteristics of the acoustic wave filter 1.

Modifications of the present example embodiment are now described below.

In one example, the acoustic wave device 100 according to the present example embodiment may include, as the acoustic wave filter 1, a plurality of the transmit filters 2, or a plurality of the receive filters 3. In another example, the acoustic wave device 100 according to Example Embodiment 1 may include, as the acoustic wave filter 1, only one of the transmit filter 2 and the receive filter 3.

The transmit filter 2 according to the present example embodiment may include, as a series-arm resonator or a parallel-arm resonator, a longitudinally-coupled resonator. The receive filter 3 according to the present example embodiment may include a longitudinally-coupled resonator as a parallel-arm resonator, or may include no longitudinally-coupled resonator.

In the acoustic wave device 100 according to the present example embodiment, the transmit filter 2 and the receive filter 3 are surface acoustic wave filters. In another example, the above-mentioned acoustic wave filters 1 may be bulk acoustic wave filters, or may be acoustic wave filters using boundary acoustic waves, plate waves, or other waves.

In the acoustic wave device 100 according to the present example embodiment, the piezoelectric substrate 10 includes the high-acoustic-velocity support substrate 15, the low-acoustic-velocity film 14, and the piezoelectric layer 13. The low-acoustic-velocity film 14 is located on the high-acoustic-velocity support substrate 15. The piezoelectric layer 13 is located on the low-acoustic-velocity film 14. The configuration of the piezoelectric substrate 10 is, however, not limited to the above-mentioned configuration. In one example, the piezoelectric substrate 10 may include, instead of the high-acoustic-velocity support substrate 15, a support substrate, and a high-acoustic-velocity film located on the support substrate, with the low-acoustic-velocity film 14 located on the high-acoustic-velocity film. In another example, the piezoelectric substrate 10 may include the piezoelectric layer 13, without the low-acoustic-velocity film 14 and the high-acoustic-velocity support substrate 15.

In the transmit filter 2 according to the present example embodiment, the attenuation band B2 is lower in frequency than the pass band B1. Alternatively, the attenuation band B2 may be higher in frequency than the pass band B1. The pass band B1 and the attenuation band B2 are not necessarily the receive frequency range and transmit frequency range, respectively, of LTE Band 20, but may be any communication bands.

An expression such as “an element is located at the first major surface of the substrate” is used herein to include not only cases where the element is mounted directly on the first major surface of the substrate, but also cases where, of two spaces separated by the substrate including a space near the first major surface and a space near the second major surface, the element is located in the space near the first major surface. That is, an expression such as “an element is located at the first major surface of the substrate” is used to include cases where the element is mounted to a location on the first major surface of the substrate with another component such as another circuit element or another electrode interposed therebetween. In one example, such an element is, but not limited to, the functional electrode 11. In one example, the substrate is the piezoelectric substrate 10. If the substrate is the piezoelectric substrate 10, the first major surface is the first major surface 101, and the second major surface is the second major surface 102.

The following aspects of various example embodiments of the present invention are disclosed herein.

An acoustic wave filter (1) according to a first aspect of an example embodiment includes a piezoelectric substrate (10), a functional electrode (11), a first wiring portion (12), a mounting substrate (20), and a second wiring portion (21). The piezoelectric substrate (10) includes a first major surface (101) and a second major surface (102) that are opposite to each other. The functional electrode (11) and the first wiring portion (12) are located at the first major surface (101) of the piezoelectric substrate (10). The first wiring portion (12) is connected to the functional electrode (11). The mounting substrate (20) includes a third major surface (201) and a fourth major surface (202) that are opposite to each other. The second wiring portion (21) is located at the third major surface (201) of the mounting substrate (20). The second wiring portion (21) is connected to ground. The first major surface (101) of the piezoelectric substrate (10), and the third major surface (201) of the mounting substrate (20) are opposite to each other. The inter-wiring distance (h1) is less than the wiring width (w1) of the first wiring portion (12). The inter-wiring distance (h1) is a distance between the first wiring portion (12), and a portion of the second wiring portion (21) that overlaps the first wiring portion (12) in plan view seen in a direction (D1) of thickness of the mounting substrate (20).

The configuration of the acoustic wave filter (1) according to the above-mentioned aspect helps to increase the likelihood of electromagnetic coupling between the first wiring portion (12) and the second wiring portion (21), and reduce the likelihood of electromagnetic coupling between the first wiring portion (12) and another wiring line within the acoustic wave filter (1). The configuration mentioned above therefore makes it possible to reduce the risk that, due to electromagnetic coupling between wiring lines within the acoustic wave filter (1), a signal that does not readily pass through the acoustic wave filter (1) is output from the acoustic wave filter (1). That is, the configuration mentioned above allows for improved attenuation characteristics of the acoustic wave filter (1).

In the acoustic wave filter (1) according to a second aspect of an example embodiment, in the first aspect, the wiring width (w1) of the first wiring portion (12) is a smallest possible value of a width of the first wiring portion (12) in a direction transverse to a direction of signal flow in the first wiring portion (12).

The configuration of the acoustic wave filter (1) according to the above-mentioned aspect makes it possible to, if the first wiring portion (12) has a non-constant wiring width (w), prevent a situation where reduction of potential electromagnetic coupling between the first wiring portion (12) and another first wiring portion (12) becomes insufficient due to the inter-wiring distance (h1) being greater than or equal to the wiring width (w1) of a portion of the first wiring portion (12).

In the acoustic wave filter (1) according to a third aspect of an example embodiment, in the first or second aspect, the acoustic wave filter (1) further includes a first terminal (23, 24), and a second terminal (25, 23). The first terminal (23, 24) is a terminal to which a signal is input. The second terminal (25, 23) is a terminal from which the signal is output. The first wiring portion (401, 414, 434) is connected to at least one of the first terminal (23, 24) or the second terminal (25, 23).

The configuration of the acoustic wave filter (1) according to the above-mentioned aspect helps to reduce potential deterioration of the attenuation characteristics of the acoustic wave filter (1), which may occur when a signal input to the acoustic wave filter (1) bypasses a series-arm resonator before being output from the acoustic wave filter (1) or may occur when a signal that is input to the acoustic wave filter (1) and that is to pass to ground is output from the acoustic wave filter (1).

In the acoustic wave filter (1) according to a fourth aspect of an example embodiment, in any one of the first to third aspects, the acoustic wave filter 1 further includes a first terminal (23, 24), a second terminal (25, 23), and a parallel-arm resonator (P11 to P22). The first terminal (23, 24) is a terminal to which a signal is input. The second terminal (25, 23) is a terminal from which the signal is output. The parallel-arm resonator (P11 to P22) is located on a parallel-arm path (Ru11 to Ru22). The parallel-arm path (Ru11 to Ru22) is located between ground, and a path (Ru1, Ru2) connecting the first terminal (23, 24) and the second terminal (25, 23). On the parallel-arm path (Ru11 to Ru22), the first wiring portion (421 to 424, 441, 443) is connected in series with the parallel-arm resonator (P11 to P22).

The configuration of the acoustic wave filter (1) according to the above-mentioned aspect makes it possible to reduce the risk that a signal that is to pass to ground from the path (Ru1, Ru2) via the parallel-arm path (Ru11 to Ru22) passes into the path (Ru1, Ru2). The configuration mentioned above therefore allows for improved attenuation characteristics of the acoustic wave filter (1).

In the acoustic wave filter (1) according to a fifth aspect of an example embodiment, in the fourth aspect, the acoustic wave filter (3) has an attenuation band (B2) that is lower in frequency than a pass band (B1) of the acoustic wave filter (3).

As a result of the configuration of the acoustic wave filter (1) according to the above-mentioned aspect, the parallel-arm path (Ru11 to Ru22) has an increased influence on the attenuation characteristics in the attenuation band (B2) of the acoustic wave filter (3). The configuration mentioned above therefore allows the attenuation characteristics of the acoustic wave filter (3) to be improved by reducing potential electromagnetic coupling between the first wiring portion (421 to 424, 441, 443) and another wiring line.

In the acoustic wave filter (1) according to a sixth aspect of an example embodiment, in the fourth or fifth aspect, the acoustic wave filter (1) includes a plurality of the parallel-arm resonators (P11 to P22). The first wiring portion (421 to 424, 441, 443) is connected to a parallel-arm resonator (P11 to P22) of the parallel-arm resonators (P11 to P22) that has a lowest impedance in an attenuation band (B2) of the acoustic wave filter (3).

The configuration of the acoustic wave filter (1) according to the above-mentioned aspect makes it possible to reduce the risk that a signal passes from one of the first wiring portions (421 to 424, 441, 443) through which the largest current flows, into the path (Ru1, Ru2) due to electromagnetic coupling between wiring lines. The configuration mentioned above therefore allows for improved attenuation characteristics of the acoustic wave filter (1).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter comprising:
a piezoelectric substrate including a first major surface and a second major surface that are opposite to each other;
a functional electrode and a first wiring portion that are located at a first major surface of the piezoelectric substrate, the first wiring portion being connected to the functional electrode;
a mounting substrate including a third major surface and a fourth major surface that are opposite to each other; and
a second wiring portion located at the third major surface of the mounting substrate, the second wiring portion being connected to ground; wherein
the first major surface of the piezoelectric substrate, and the third major surface of the mounting substrate are opposite to each other; and
an inter-wiring distance is less than a wiring width of the first wiring portion, the inter-wiring distance being a distance between the first wiring portion and a portion of the second wiring portion that overlaps the first wiring portion in plan view seen in a direction of thickness of the mounting substrate.

2. The acoustic wave filter according to claim 1, wherein the wiring width of the first wiring portion is a smallest possible value of a width of the first wiring portion in a direction transverse to a direction of signal flow in the first wiring portion.

3. The acoustic wave filter according to claim 1, further comprising:
a first terminal to which a signal is input; and
a second terminal from which the signal is output; wherein
the first wiring portion is connected to at least one of the first terminal or the second terminal.

4. The acoustic wave filter according to claim 1, further comprising:
a first terminal to which a signal is input;
a second terminal from which a signal is output; and
a parallel-arm resonator on a parallel-arm path located between ground and a path connecting the first terminal and the second terminal; wherein
on the parallel-arm path, the first wiring portion is connected in series with the parallel-arm resonator.

5. The acoustic wave filter according to claim 4, wherein the acoustic wave filter has an attenuation band that is lower in frequency than a pass band of the acoustic wave filter.

6. The acoustic wave filter according to claim 4, further comprising:
a plurality of the parallel-arm resonators; wherein
the first wiring portion is connected to a parallel-arm resonator of the parallel-arm resonators that has a lowest impedance in an attenuation band of the acoustic wave filter.

7. The acoustic wave filter according to claim 1, further comprising an external connection electrode at the fourth major surface of the mounting substrate.

8. The acoustic wave filter according to claim 1, further comprising a plurality of external connection electrodes.

9. The acoustic wave filter according to claim 8, wherein each of the plurality of external connection electrodes includes a common electrode, an input electrode and a ground electrode.

10. The acoustic wave filter according to claim 1, further comprising a spacer between the piezoelectric substrate and the mounting substrate, and a via conductor extending through the spacer to electrically connect the first wiring portion to an external connection electrode.

11. The acoustic wave filter according to claim 1, further comprising a transmit filter and a receiving filter.

12. The acoustic wave filter according to claim 1, wherein the acoustic wave filter is a duplexer.

13. The acoustic wave filter according to claim 11, wherein the transmit filter is a ladder filter including a plurality of acoustic wave resonators.

14. The acoustic wave filter according to claim 13, wherein the plurality of acoustic wave resonators includes series-arm resonators and parallel-arm resonators.

15. The acoustic wave filter according to claim 11, wherein the receive filter is a ladder filter including a plurality of acoustic wave resonators.

16. The acoustic wave filter according to claim 15, wherein the plurality of acoustic wave resonators includes series-arm resonators and parallel-arm resonators.

17. The acoustic wave filter according to claim 10, wherein the spacer is made of an insulating material.

18. The acoustic wave filter according to claim 1, wherein the acoustic wave filter is an acoustic wave resonator.

19. The acoustic wave filter according to claim 1, wherein the acoustic wave filter is a bulk acoustic wave resonator.

20. The acoustic wave filter according to claim 11, wherein the transmit filter and the receive filter include different numbers of functional electrodes.
